(19) United States
(12) Patent Application Publication
(10) Pub. No.: US 2010/0078070 A1
(43) Pub. Date: Apr. 1, 2010

(54) SOLAR BATTERY

(75) Inventors: YOICHI HOSOYA, KANAGAWA (JP); TAKESHI FUNAKUBO, KANAGAWA (JP); NORI MIYAGISHIMA, KANAGAWA (JP); KENJI NAOI, KANAGAWA (JP); RYOJI NISHIMURA, KANAGAWA (JP); TERUHIKO KURAMACHI, KANAGAWA (JP)

Correspondence Address: YOUNG & THOMPSON, 209 Madison Street, Suite 500, Alexandria, VA, 22314, US

(73) Assignee: FUJIFILM CORPORATION, Tokyo (JP)

(21) Appl. No.: 12/568,901

(22) Filed: Sep. 29, 2009

(30) Foreign Application Priority Data
Sep. 30, 2008 (JP) 2008-252726

(51) Int. Cl. H01L 31/00

(52) U.S. Cl. 136/256

(57) ABSTRACT

A solar battery, which contains a transparent conductive layer having an average transmittance of 80% or more with an electromagnetic wave having a wavelength of 1,100 nm to 2,000 nm, and a sheet resistance of 20 ohm/sq. or less, in which the transparent conductive layer contains metal nanowires.

### BACKGROUND OF THE INVENTION

1. Field of the Invention

The present invention relates to a solar battery containing a transparent conductive layer which attains both transparency with light of the infrared region and conductivity transparent conductive layer.

2. Description of the Related Art

Attentions have been drawn to solar batteries as clean energy sources. Especially, thin film solar batteries, which have a small usage amount of raw materials, are becoming essential for the distribution of solar batteries in the future. Meanwhile, it is important to increase conversion efficiency of a solar battery, and thus researches and studies have been undergone therefor. In order to convert light of various wavelengths from sunlight shining to the earth to electric energy, various attempts have been made for absorbing light of longer wavelengths.

For example, a so-called a tandem type, in which materials having absorption at from short wavelengths to long wavelengths are combined, and a CIGS solar battery in which a material having a large absorbed amount for long wavelengths is used have been studied, and improvements have been made for attaining high efficiency.

Improvements for optical absorption at long wavelengths have been studied for the purpose of improving conversion efficiency as mentioned earlier. To this end, optical absorption of a transparent electrode, which functions to take electric energy from the solar battery, becomes important as well. ITO or zinc oxide, which is commonly used as a transparent electrode of a solar battery, is applied with mainly N-type dormant for providing conductivity. When the doping amount is increased so as to improve conductivity, however, there is a problem such that the transmittance at long wavelengths is lowered.

In the case where the solar battery having high absorption of long wavelengths is used, however, light absorbed at a long wavelength range cannot passes through a transparent electrode, which preventing the improvement of efficiency. Therefore, there has been proposed an attempt for improving the transmittance at long wavelengths by selecting or adjusting a doping element and an amount thereof to be added to oxide (Japanese Patent Application Laid-Open (JP-A) Nos. 2004-207221 and 2007-273455).

However, these proposals are still insufficient for improving the conversion efficiency, and thus it is current situation that further improvement of the transmittance in the long wavelength range.

### BRIEF SUMMARY OF THE INVENTION

The present invention aims at providing a solar battery containing a transparent conductive layer which has a high transmittance with the light of the infrared region and a low sheet resistance, and which contains metal nanowires.

The means for solving the aforementioned problems are as follow:

<1> A solar battery, containing: a transparent conductive layer having an average transmittance of 80% or more with an electromagnetic wave having a wavelength of 1,100 nm to 2,000 nm, and a sheet resistance of 20 ohm/sq. or less, the transparent conductive layer containing metal nanowires.
<2> The solar battery according to <1>, wherein the transparent conductive layer has a larger conductivity in a planar direction thereof than that in a thickness direction thereof.
<3> The solar battery according to any of <1> or <2>, wherein the metal nanowire has a diameter of 50 nm or less, and a length of 5 μm or more, and wherein an amount of the metal nanowires contained in total metal particles of the transparent conductive layer is 50% by mass or more on the basis of a metal content.
<4> The solar battery according to any one of <1> to <3>, wherein the metal nanowire contains silver.
<5> The solar battery according to any one of <1> to <4>, further containing a light-absorbing semiconductor layer containing silicon.
<6> The solar battery according to any one of <1> to <4>, further containing a light-absorbing semiconductor layer formed of Ib group element, IIIb group element, and VIb group element.
<7> The solar battery according to <6>, wherein the light-absorbing semiconductor layer contains at least one element selected from Cu, Ag, In, Ga, S, Se and Te.

According to the present invention, the problems in the art can be solved, and there is provided a solar battery containing a transparent conductive layer which has a high transmittance with the light of the infrared region and a low sheet resistance, and which contains metal nanowires.

### BRIEF DESCRIPTION OF THE DRAWINGS

FIG. 1 is an explanatory diagram illustrating a method for obtaining a sharpness of a metal nanowire;

FIG. 2A is a process diagram showing an example of a method for producing a cell of a CIGS thin film solar battery;

FIG. 2B is a process diagram showing an example of a method for producing a cell of a CIGS thin film solar battery;

FIG. 2C is a process diagram showing an example of a method for producing a cell of a CIGS thin film solar battery;

FIG. 2D is a process diagram showing an example of a method for producing a cell of a CIGS thin film solar battery; and

FIG. 3 is a diagram showing the relationship between a lattice constant and band gap of the semiconductor formed of the Ib group element, IIIb group element, and VIb group element.

### DETAILED DESCRIPTION OF THE INVENTION

### Solar Battery

A solar battery of the present invention contains a transparent conductive layer, and may contain other members, if necessary.

The solar battery is composed of, for example, a substrate, a lower electrode, a solar battery device, and an upper electrode, and at least one of the lower electrode and the upper electrode contains the transparent conductive layer.

### <Transparent Conductive Layer>

The transparent conductive layer has an average transmittance of 80% or more, preferably 85% or more, with an electromagnetic wave having a wavelength of 1,100 nm to 2,000 nm. When the average transmittance is less than 80%, an amount of light reaching to a photoelectric conversion layer becomes insufficient and thus the conversion efficiency is lowered.

The average transmittance can be obtained, for example, by measuring the transmittance at the wavelength of 400 nm to 2,700 nm by means of UV-3150 manufactured by Shimadzu Corporation, and obtaining an average of the transmittance at the wavelength of 1,100 nm to 2,000 nm.

Moreover, the transparent conductive layer has a sheet resistance of 20 ohm/sq. or less, preferably 10 ohm/sq. or less. When the sheet resistance is more than 20 ohm/sq., the amount of the electrons, which has been generated in a photoelectric conversion layer, lost as heat as passing through the transparent conductive layer is increased, thus lowering the conversion efficiency.

In the solar battery device, the transparent conductive layer functions to collect power from the photoelectronic conversion element (the photoelectronic conversion layer), and the collected power is further collected by the extraction electrode. Here, a current runs through the transparent conductive layer in the planar direction thereof. Moreover, in the case where the photoelectronic conversion elements are integrated, a current runs inside the transparent conductive layer in the planar direction thereof. In such manners, in the solar battery device, a current runs through the transparent conductive layer in the planar direction thereof. Accordingly, it is important that the resistance in the planar direction thereof is low. Namely, it is preferable that the conductivity of the transparent conductive layer in the planar direction is larger than that in the thickness direction. Specifically, a ratio (Rs/Rt) of the electric resistance Rs of the transparent conductive layer in the planar direction to the electric resistance Rt in the thickness direction is preferably 1.2 to 1,000, more preferably 2.0 to 100.

The conductivity is measured by the following method. At first, a transparent conductive layer is formed on a conductive substrate, metal electrodes are disposed on the conductive substrate and the transparent conductive layer, respectively, and a voltage is applied to thereby measure a resistance in the thickness direction. Next, metal electrodes are disposed on two regions of the transparent conductive layer, respectively, and a voltage is applied to thereby measure a resistance in the planar direction. For the method for measuring the resistance, for example, the disclosures of JP-A Nos. 2004-45109 and 2000-88900 can be referred.

The transparent conductive layer contains metal nanowires, and may further contain other substances, if necessary.

When the metal nanowires are contained in the transparent conductive layer, the metal nanowires are laid in the planar direction of the transparent conductive layer so that the metal nanowires are brought into contact with each other to thereby provide conductivity to the transparent conductive layer. As a consequence,

By adding the metal nanowires to the transparent conductive layer, the metal nanowires are lied in the planar direction, the metal nanowires are brought into contact to each other to thereby have a conductivity. Here, a current tends to run more easily in the planar direction than the thickness direction, and thus the electric resistance Rs of the planar direction can be lowered as mentioned above. Therefore, it is preferred that the metal nanowires are contained in the transparent conductive layer.

### [Metal Nanowire]

The metal nanowire has a diameter of 50 nm or less and a major axis length of 5 μm or more, and in the total metal particles, the metal nanowires having such diameter and major axis length are contained in an amount of 50% by mass or more on the basis of the metal content.

In the present invention, the metal nanowire is defined as a metal particle having an aspect ratio (major axis length/diameter) of 30 or more.

The diameter (minor axis length) of the metal nanowire is preferably 50 nm or less, more preferably 35 nm or less, yet more preferably 20 nm or less. When the diameter thereof is too small, the antioxidation property thereof is degraded, causing the durability of the metal nanowire. Therefore, the diameter of the metal nanowire is preferably 5 nm or more. When the diameter thereof is more than 50 nm, there are cases where sufficient transparency cannot be attained, probably because the scattering is occurred due to the metal nanowires.

The major axis length of the metal nanowire is preferably 5 μm or more, more preferably 10 μm or more, yet more preferably 30 μm or more. When the major axis length of the metal nanowire is too long, aggregated matters may be generated during the production probably because the metal nanowires are tangled each other. Therefore, the major axis length of the metal nanowire is preferably 1 mm or less. When the major axis length of the metal nanowire is less than 5 μm, sufficient conductivity may not be attained probably because it is difficult to form a dense network.

Here, the diameter and major axis length of the metal nanowire can be obtained, for example, by using a transmission electron microscope (TEM) and an optical microscope, and observing images of TEM or the optical microscope. In the present invention, the diameter and major axis length of the metal nanowire are obtained by observing three hundred metal nanowires by means of a transmission electron microscope (TEM), and calculating the average values thereof.

In the embodiment of the present invention, the metal nanowires each having the diameter of 50 nm or less and the major axis length of 5 μm or more are contained in the total metal particles preferably in an amount of 50% by mass or more, more preferably 60% by mass or more, yet more preferably 75% by mass or more on the basis of the metal content.

When the proportion of the metal nanowires each having the diameter of 50 nm or less and major axis length of 5 μm or more (hereinafter, may be referred as an appropriate wire yield) is less than 50% by mass, the conductivity may be lowered probably because the metal content contributes to the conductivity is reduced, and the durability may be degraded probably because a dense wire network cannot be formed at the same time to thereby cause a voltage concentration. Moreover, in the case where the plasmon absorption of particles having the shape other than the nanowire is strong, such as the case of spherical particles, the transparency is degraded.

Here, the appropriate wire yield can be obtained, for example when the metal nanowire is a silver nanowire, by filtering silver nanowire aqueous solution so as to separate the silver nanowires from the other particles, and measuring the amount of Ag remained on the filter paper, and the amount of Ag passed through the filter paper, respectively, by means of ICP Atomic Emission Spectrometer. The metal nanowires remained on the filter paper are observed under TEM, among them the diameters of the three hundred metal nanowires are observed, and check the distribution thereof, to thereby confirm that they are the metal nanowires having the diameter of 50 nm or less and the major axis length of 5 μm or more. Note that, as the filter paper, those having a pore size that is five times or more of the maximum major axis length of particles other than the metal nanowires and is ½ or less of the minimum major axis length of the metal nanowires are preferably used, where the maximum major axis length of the particles other than the metal nanowires is measured based on the image of TEM.

The variation coefficient of the diameters of the metal nanowires for use in the present invention is preferably 40% or less, more preferably 35% or less, yet more preferably 30% or less.

When the variation coefficient is more than 40%, the durability may be degraded probably because the voltage is concentrated on wires having small diameters.

The variation coefficient of the diameters of the metal nanowires can be obtained, for example, by measuring diameters of three hundred metal nanowires on an image of transmission electron microscope (TEM), and calculating the standard deviation and average value thereof.

The shape of the metal nanowire can be appropriately selected, for example cylinder, rectangular parallelepiped, or column having a cross section in the shape of polygon. For use requiring high transparency, it is preferably a cylinder or those having a cross section of polygon angles of which are rounded.

The cross sectional shape of the metal nanowire can be checked by applying metal nanowire aqueous dispersion onto a substrate, and observing the cross section of the coated layer of the metal nanowire aqueous dispersion, which is cut in the perpendicular direction relative to the major axises of nanowires, under a transmission electron microscope (TEM).

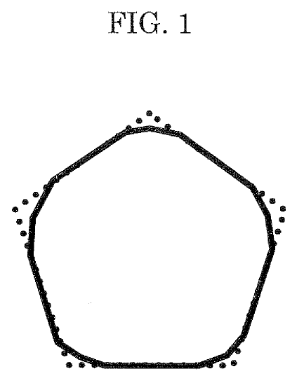

The angle of the cross section of the metal nanowire means a surrounding area of the point where an extended line from each side of the cross section and a vertical line from the adjacent side meets. Moreover, “each side of the cross section” is a straight light connecting the angle to the adjacent angle. In this case, a sharpness is determined as a ratio of the “circumference of the cross section” to the total length of “each side of the cross section”. The sharpness can be represented by, for example in the case of the cross section of the metal nanowire shown in FIG. 1, a ratio of the circumference of the cross section shown with the solid line to the circumference of the pentagon shown with the dotted line. Here, the cross sectional shape having the sharpness of 75% or less is determined as the cross sectional shape having rounded angles. The sharpness is preferably 60% or less, more preferably 50% or less. When the sharpness is more than 75%, a transparency is degraded such as leaving yellowish color, probably because electrons are localized at the angle and thus plasmon absorption is increased.

A metal used for the metal nanowires is not particularly limited in terms of the selection thereof, and any metal can be used for the metal nanowires. Other than using one metal, two or more metal may be used in combination, or as an alloy. Among those examples, those formed of a metal or a metal compound is preferable, and those formed of the metal is more preferable.

The metal is preferably at least one metal selected from the 4^{th}, 5^{th} and 6^{th} periods of the long form of Periodic Table (IUPAC 1991), more preferably from the 2^{nd} to 14^{th} groups thereof, and yet more preferably from the 2^{nd} group, the 8^{th} group, 9^{th} group, 10^{th} group, 11^{th} group, 12^{th} group, 13^{th} group and 14^{th} group. Moreover, it is particularly preferred that at least one of the aforementioned elements be contained in the metal as a main component.

Examples of the metal include copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, and alloys thereof. Among them, copper, silver, gold, platinum, palladium, nickel, tin, cobalt, rhodium, iridium, and alloys thereof are preferable, palladium, copper, silver, gold, platinum, tin and alloys thereof are more preferable, and silver and alloy containing silver are particularly preferable.

### <Production Method of Metal Nanowire>

The method for producing the metal nanowires contains a heating step that is adding a metal complex solution to an aqueous medium containing at least a halogen compound and a reducing agent and heating at the temperature of 150° C. or less, and may further contain a desalination step, if necessary.

The metal complex is suitably selected depending on the intended purpose without any restriction, but a silver complex is particularly preferable as the metal complex. A ligand of the silver complex is, for example, CN⁻, SCN⁻, SO₃²⁻, thiourea, ammonium, or the like. The details related to such ligands can be referred to the description in “The Theory of the Photographic Process 4^{th} Edition” T. H. James, Macmillan Publishing. Among them, a silver ammonium complex is particularly preferable. The timing for adding the metal complex is preferably after adding the dispersing agent and the halogen compound. By adding the metal complex at this timing, the proportion of the metal nanowires having diameters and major axis lengths desired in the present invention can be increased probably because wire cores are yielded at a high probability.

As the medium, a hydrophilic medium is preferable. Examples of the hydrophilic medium include: water; alcohols such as methanol, ethanol, propanol; isopropanol, and butanol; ethers such as dioxane, and tetrahydrofuran; and ketenes such as acetone.

The heating temperature is preferably 150° C. or less, more preferably 20° C. to 130° C., yet more preferably 30° C. to 100° C., particularly preferably 40° C. to 90° C. If necessary, the temperature may be changed during the formation of particles. To change the temperature in the middle of the formation of particles may contribute to the control for the formation of the core, preventing the generation of re-grown cores, and selective acceleration of the growth to thereby improve the monodispersibility.

When the heating temperature is more than 150° C., the transmittance may be lowered in terms of the evaluation of the coated film, probably because the angles of the cross section of the metal nanowire become sharp. Moreover, as the heating temperature is getting lower, the metal nanowires tends to tangle and dispersion stability thereof is lowered, probably because the yield of core is lowered and the metal nanowires become too long. This tendency becomes significant at the heating temperature of 20° C. or less.

It is preferred that the reducing agent be added at the time of the heating. The reducing agent is suitably selected from those generally used without any restriction. Examples of the reducing agent include: metal salts of boron hydrides such as sodium boron hydride and potassium boron hydride; aluminum salt hydrides such as lithium aluminum hydride, potassium aluminum hydride, cesium aluminum hydride, beryllium aluminum hydride, magnesium aluminum hydride, and calcium aluminum hydride; sodium sulfites; hydrazine compounds; dextrins; hydroquinones; hydroxylamines; citric acids and salts thereof ascorbic acids and salts thereof; alkanol amines such as diethylamino ethanol, ethanol amine, propanol amine, triethanol amine, and dimethylamino propanol; aliphatic amines such as propyl amine, butyl amine, dipropylene amine, ethylene diamine, and triethylenepentane amine; heterocyclic amines such as piperidine, pyrrolidine, N-methylpyrrolidine, and morpholine; aromatic amines such as aniline, N-methyl aniline, toluidine, anisidine, and phenetidine; aralkyl amines such as benzyl amine, xylene diamine, and N-methylbenzyl amine; alcohols such as methanol, ethanol and 2-propanol; ethylene glycol; glutathione; organic acids such as citric acid, malic acid, and tartaric acid; reducing sugars such as glucose, galactose, mannose, fructose, sucrose, maltose, raffinose, and stachyose; and sugar alcohols such as sorbitol. Among them, the reducing sugars and sugar alcohols that are derivatives of the reducing sugars are particularly preferable. Note that, there is a case where the reducing agents may also function as a dispersing agent depending on the types of the reducing agents for use, and those reducing agents are also preferably used.

The timing for adding the reducing agent may be before or after adding a dispersing agent, and may be before or after adding a halogen compound.

It is preferred that the halogen compound be added at the time of the formation of the metal nanowires.

The halogen compound is suitably selected depending on the intended purpose without any restriction, provided that the compound contains bromine, chlorine, or iodine. Preferable examples of the halogen compound include: alkali halaide such as sodium bromide, sodium chloride, sodium iodide, potassium bromide, potassium chloride, and potassium iodide; and compounds that can be used together with the dispersing agent described below. The timing for adding the halogen compound may be before or after adding the dispersing agent, and before or after adding the reducing agent. Note that, there is a case where the halogen compounds may also function as a dispersing agent depending on the types of the halogen compounds for use, and those halogen compounds are also preferably used.

Halogenated silver fine particles may be used as a replacement of the halogen compound, or the halogen compound and the halogenated silver fine particles may be used in combination.

The dispersing agent and the halogen compound or halogenated silver fine particles may be formed of the same material. The compound used for both the dispersing agent and the halogen compound is, for example, hexadecyl-trimethylammonium bromide (HTAB) containing amino group and bromide ion, or hexadecyl-trimethylammonium chloride (HTAC) containing amino group and chloride ion.

It is preferred that the dispersing agent be added at the time of the formation of the gold nanowires.

The timing for adding the dispersing agent may be before preparing particles in the presence of dispersion polymer, or after preparing particles for controlling the dispersion state of the particles. In the case where the addition of the dispersing agent is carried out more than twice, the amount of the dispersion agent to be added each time needs to be adjusted depending on the desired length (major axis length) of wires. This is because it is considered that the length of wires is affected by the control of the amount of the metal particles serving as cores.

Examples of the dispersing agent include amino group-containing compounds, thiol group-containing compounds, sulfide group-containing compounds, amino acids or derivatives thereof, peptide compounds, polysaccharides, natural polymers derived from polysaccharides, synthetic polymers, and polymers derived from those mentioned above such as gels.

Examples of the polymers include protective colloid polymers such as gelatin, polyvinyl alcohol, methyl cellulose, hydroxypropyl cellulose, polyalkylene amine, partial alkyl ester of polyacrylic acid, polyvinyl pyrrolidone, and polyvinyl-pyrrolidine copolymer.

The compound structures usable for the dispersing agent can be, for example, referred to the description in Pigment Dictionary (edited by Seishiro Ito, published by ASAKURA PUBLISHING CO., (2000)).

Depending on the type of the dispersing agent for use, shapes of obtained metal nanowires can be changed.

The desalination can be carried out by ultrafiltration, dialysis, gel filtration, decantation, centrifugal separation, or the like, after forming the metal nanowires.

### [Aqueous Dispersion]

The aqueous dispersion is a dispersion medium containing the metal nanowires therein.

The amount of the metal nanowires contained in the aqueous dispersion is preferably 0.1% by mass to 99% by mass, more preferably 0.3% by mass to 95% by mass. When the amount is less than 0.1% by mass, the load at a drying process during the production becomes excessive. When the amount is more than 99% by mass, particles tend to aggregate to each other.

As the dispersion medium of the aqueous dispersion, water is mainly used, and an organic solvent miscible with water may be used in combination at the proportion of 80 vol. % or less.

As the organic solvent, for example, alcohol compounds having a boiling point of 50° C. to 250° C., more preferably 55° C. to 200° C. are suitably used. By using such alcohol compound in combination with water, a coating performance can be improved at the coating step, and drying load can be reduced.

The alcohol compound is suitably selected depending on the intended purpose without any restriction. Examples of thereof include methanol, ethanol, ethylene glycol, diethylene glycol, triethylene glycol, polyethylene glycol 200, polyethylene glycol 300, glycerin, propylene glycol, dipropylene glycol, 1,3-propane diol, 1,2-butane diol, 1,4-butane diol, 1,5-pentane diol, 1-ethoxy-2-propanol, ethanol amine, diethanol amine, 2-(2-aminoethoxy)ethanol, and 2-dimethylamino isopropanol. Among them, ethanol and ethylene glycol are preferable. These may be used singly or in combination of two or more.

It is preferred that the aqueous dispersion do not contain inorganic ions such as alkali metal ions, alkali earth ions, and halide ions as much as possible.

The electric conductivity of the aqueous dispersion is preferably 1 mS/cm or less, more preferably 0.1 mS/cm or less, yet more preferably 0.05 mS/cm or less.

The viscosity of the aqueous dispersion is preferably 0.5 mPa·s to 100 mPa·s, more preferably 1 mPa·s to 50 mPa·s at 20° C.

The aqueous dispersion may contain various additives such as a surfactant, a polymerizable compound, an antioxidant, a sulfuration inhibitor, a corrosion inhibitor, a viscosity modifier, an antiseptic agent, and the like, if necessary.

The corrosion inhibitor is suitably selected depending on the intended purpose without any restriction. Azoles are suitable for the corrosion inhibitor. Examples of the azoles are at least one selected from benzotriazol, tolytriazole, mercaptobenzothiazole, mercaptobenzotriazol, mercaptobenzotetrazol, (2-benzothiazolylthio)acetic acid, 3-(2-benzothiazolylthio)propionic acid, alkali metal salts thereof, ammonium salts thereof, and amine salts thereof. By adding the corrosion inhibitor, an excellent anticorrosion effect can be further enhanced. The corrosion inhibitor may be added in the state of the dissolved solvent in which the corrosion inhibitor is dissolved in a suitable solvent, or in the form of powder. Alternatively, after forming a transparent conductor described later, the corrosion inhibitor can be applied by immersing the transparent conductor in the bath of the corrosion inhibitor.

### <Solar Battery Device>

The solar battery device for use in the present invention is suitably selected from the ones commonly used as a solar battery device without any restriction. Examples of the solar battery device include a single crystal silicon solar battery device, polycrystalline silicon solar battery device, an amorphous silicon solar battery device of a single junction or tandem structure, a III-V group compound semiconductor solar battery device using the III-V group compound such as gallium arsenide (GaAs) and indium phosphide (InP), a II-VI group compound semiconductor solar battery device using the II-VI group compound such as cadmium tellurium (CdTe), a group compound semiconductor solar battery device of copper/indium/selenium type (so-called, CIS type), copper/indium/gallium/selenium type (so-called, CMS type), or copper/indium/gallium/selenium/sulfur type (so-called, CIGSS type), a dye-sensitized solar battery device, and an organic solar battery device. Among them, in the present invention, the amorphous silicon solar battery device of a tandem structure, and the I-III-VI group compound semiconductor solar battery device of copper/indium/selenium type (so-called, CIS type), copper/indium/gallium/selenium type (so-called, CIGS type), or copper/indium/gallium/selenium/sulfur type (so-called, CIGSS type) are preferable.

In the case of the amorphous silicon solar battery device of the tandem structure, a tandem structure of two or more layers selected from amorphous silicon, microcrystal silicon thin layer, and a thin layer containing Ge is used as a photoelectric conversion layer. For the formation of the layer, a plasma-enhanced chemical vapor deposition (PECVD) or the like is used.

### [Production Method of Transparent Conductive Layer]

The transparent conductive layer for use in the solar battery of the present invention is suitably applied for all of the solar battery devices listed above. The transparent conductive layer may be contained in any part of the solar battery device, but is preferably contained so as to be adjacent to the photoelectric conversion layer. With regard to the positioning of the transparent conductive layer and the photoelectric conversion layer, the structures listed below are preferable, but not limited thereto. Moreover, the structures below do not describe all of the parts constituting the solar battery device, and they only describe within the range where the positioning of the transparent conductive layer can be illustrated.

(A) substrate-transparent conductive layer (a product from the present invention)-photoelectric conversion layer
(B) substrate-transparent conductive layer (a product from the present invention)-photoelectric conversion layer-transparent conductive layer (a product from the present invention)
(C) substrate-electrode-photoelectric conversion layer-transparent conductive layer (product from the present invention)
(D) back side electrode-photoelectric conversion layer-transparent conductive layer (a product from the present invention)

The method for forming the transparent conductive layer includes applying the aqueous dispersion onto a substrate and drying the aqueous dispersion.

After applying the aqueous dispersion, annealing may be carried out by heating. At the time of the annealing, the heating temperature is preferably 50° C. to 300° C., more preferably 70° C. to 200° C.

The method for applying the aqueous dispersion is suitably selected depending on the intended purpose without any restriction. Examples thereof include web coating, spray coating, spin coating, doctor blade coating, screen printing, gravure printing, and inkjet printing. Especially with the web coating, screen printing and inkjet printing, a roll-to-roll production on a flexible substrate can be possible.

Examples of the substrate are listed below, but are not limited thereto.

(1) glass such as quartz glass, non-alkali glass, crystallized transparent glass, Pyrex® glass, sapphire
(2) thermoplastic resin such as acrylic resin, e.g. polycarbonate, polymethacrylate; vinyl chloride resin, e.g. polyvinyl chloride, vinyl chloride copolymer; polyacrylate; polysulfone; polyether sulfone; polyimide; PET; PEN; fluororesin; phenoxy resin; polyolefine resin; nylon; styrene resin; and ABS resin
(3) thermoset resin such as epoxy resin

A surface of the substrate may be provided with a treatment to give hydrophilicity. Moreover, as the substrate, the one a surface of which is coated with a hydrophilic polymer is preferable. By these treatment, a coating performance and adhesion of the aqueous dispersion to the substrate are improved.

The treatment for hydrophilicity is suitably selected depending on the intended purpose without any restriction. Examples thereof include a chemical treatment, physical roughening, corona discharge, flame treatment, ultraviolet ray treatment, glow discharge, active plasma treatment, and laser treatment. It is preferred that the surface tension of the surface of the substrate become 30 dyne/cm or more as a result of the surface treatment.

The hydrophilic polymer for applying to the surface of the substrate is suitably selected depending on the intended purpose without any restriction. Examples thereof include gelatin, gelatin derivatives, casein, agar, starch, polyvinyl alcohol, polyacrylic acid copolymer, carboxymethyl cellulose, hydroxyethyl cellulose, polyvinyl pyrrolidine, and dextran.

A thickness of the hydrophilic polymer layer (dry basis) is preferably 0.001 μm to 100 μm, more preferably 0.01 μm to 20 μm.

A hardening agent is preferably added to the hydrophilic polymer layer so as to increase the film strength. The hardening agent is suitably selected depending on the intended purpose without any restriction. Examples of thereof include: aldehyde compounds such as formaldehyde, and glutaraldehyde; ketone compounds such as diacetyl and cyclopentanedione; vinyl sulfone compounds such as divinyl sulfone; triazine compounds such as 2-hydroxy-4,6-dichloro-1,3,5-triazine; and isocyanate compounds described in U.S. Pat. No. 3,103,437.

The hydrophilic polymer layer is formed by the following manner. A coating liquid is prepared by dissolving and/or dispersing the aforementioned compound in a solvent such as water; the obtained coating liquid is applied to a surface of the substrate, which has been treated to give hydrophilicity, by a coating method such as spin coating, dip coating, extrusion coating, bar coating and die coating; the coated layer is dried. The temperature for the drying is preferably 120° C. or less, more preferably 30° C. to 100° C., yet more preferably 40° C. to 80° C.

Moreover, an undercoat layer may be formed between the substrate and the hydrophilic polymer layer for improving the adhesion.

### —CIGS Solar Battery—

Hereinafter, a CIGS solar battery is precisely explained.

### —Structure of Photoelectric Conversion Layer—

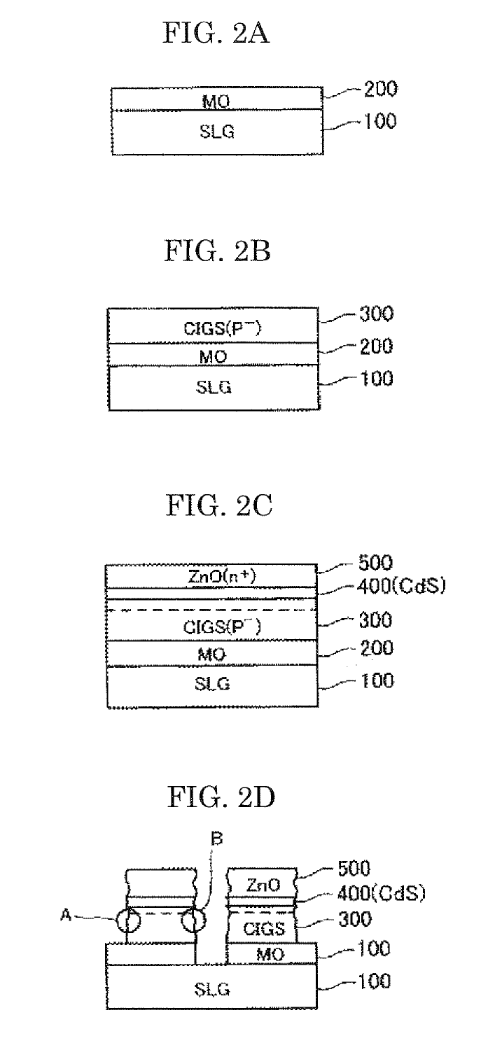

A thin film solar battery using CuInSe₂ (CIS thin film), which is a semiconductor thin film of a chalcopyrite structure consisting of a Ib group element, a IIIb group element, and a VIb group element, or Cu(In,Ga)Se₂ (CIGS thin film), in which Ga is solid saluted to CuInSe₂, for a light absorption layer has high energy conversion efficiency, and the efficiency thereof is deteriorated due to radiation of light at only a small degree. FIGS. 2A to 2D are cross sectional diagrams of the device for explaining the conventional production method of the cell of a CIGS thin film solar battery.

As shown in FIG. 2A, a molybdenum (Mo) electrode layer 200, which will be a lower electrode with respect to the plus side, is formed on a substrate 100. Then, as shown in FIG. 2B, a light absorption layer 300 formed of CIGS thin film exhibiting p-type as a result of the adjustment of the composition is formed on the Mo electrode layer 200. Subsequently, as shown in FIG. 2C, a buffer layer 400 of CdS or the like is formed on the light absorption layer 300, and a transparent electrode 500, which exhibits n⁺ type by the doping of impurities, serves as an upper electrode at the minus side, and is formed of zinc oxide (ZnO), is formed on the buffer layer 400. As shown in FIG. 2D, a scribing processing is carried out at the same time from the transparent electrode layer 500 formed of ZnO to the Mo electrode layer 200 by means of a mechanical scribe device. By this processing, each cell of the thin film solar battery is electrically separated (i.e., each cell is individualized). The compounds with which a film can be suitably formed in this embodiment are listed below.

(1) Compounds containing a element, compound or alloy that becomes Elements that becomes a fluid phase at a room temperature or by heating
(2) Chalcogen compound (compound containing S, Se, and Te)

II-VI group compound: ZnS, ZnSe, ZnTe, CdS, CdSe, CdTe, etc.

I-III-VI₂ group compound: CuInSe₂, CuGaSe₂, Cu(In,Ga)Se₂, CuInS₂, CuGaSe₂, Cu(In,Ga)(S,Se)₂, etc.

I-III₃-VI₅ group compound: CuIn₃Se₅, CuGa₃Se₅, Cu(In,Ga)₃Se₅, etc.

(3) Compound of chalcopyrite structure and Compound of defect stannite structure

I-III-VI₂ group compound: CuInSe₂, CuGaSe₂, Cu(In,Ga)Se₂, CuInS₂, CuGaSe₂, Cu(In,Ga)(S,Se)₂, etc.

I-III₃-VI₅ group compound: CuIn3₃e₅, CuGa₃Se₅, Cu(In,Ga)₃Se₅, etc.

Note that, in the above, (In,Ga) and (S,Se) respectively represent (In₁₋ₓ,Gaₓ) and (S_{1-y}Se_{y}), where x=0 to 1 and y=0 to 1.

Hereinafter, typical examples of the formation method of CIGS layer are described, but the formation method thereof is not limited to these examples.

### 1) Multiple Source Simultaneous Deposition

The typical methods of the multiple source simultaneous deposition are a three-stage deposition developed by NREL (National Renewable Energy Laboratory), USA, and a simultaneous deposition developed by EC Group. The three-stage deposition is described, for example, in J. R. Tuttle, J. S. Ward, A. Duda, T. A. Berens, M. A. Contreras, K. R. Ramanathan, A. L. Tennant, J. Keane, E. D. Cole, K. Emery and R. Noufi: Mat. Res. Soc. Symp. Proc., vol. 426 (19%) p. 143. Moreover, the simultaneous deposition is described, for example, in L. Stolt et al.: Proc. 13th ECPVSEC (1995, Nice) 1451.

The three-stage deposition is a method in which In, Ga and De are simultaneously deposited at the substrate temperature of 300° C. in high vacuum, then the temperature is elevated to 500° C. to 560° C. to thereby simultaneously deposit Cu and Se, and thereafter In, Ga, and Se are further simultaneously deposited, to thereby obtain a graded band gap CIGS film a forbidden band width of which is inclined. The method of EC Group is an improved method based on a bilayer deposition method developed by Boeing, in which Cu excess CIGS is deposited at the initial state and In excess CIGS is deposited in later stage, so as to be able to apply the method to the inline process. The bilayer deposition method is described in W. E. Devaney, W. S. Chen, J. M. Stewart, and R. A. Mickelsen: IEEE Trans. Electron. Devices 37 (1990) 428.

Both of the three-stage deposition and the simultaneous deposition of EC Group form Cu excess CIGS film composition in the process of growing the film and utilize a liquid phase sintering of the liquid phase Cu₂₋ₓSe (x=0 to 1) which is obtained from the phase separation from the Cu excess CIGS. Therefore, large grains grow and the CIGS film having excellent crystallinity can be obtained in these methods.

Furthermore, various methods have recently been studied to modify the method mentioned above for improving the crystallinity of the CIGS film, and these methods can be also used.

### (a) Method Using Ionized Ga

This is a method to ionize Ga by passing evaporated Ga through a grid on which thermions generated by a filament are present. The ionized Ga is accelerated by extraction voltage and then supplied to the substrate. The details thereof are described in H. Miyazaki, T. Miyake, Y. Chiba, A. Yamada, M. Konagai, phys. stat. sol. (a), Vol. 203 (2006) p. 2603.

### (b) Method Using Cracked Se

The evaporated Se generally forms clusters, but it is a method to make Se clusters lower molecule by thermally decomposing the Se clusters by means of a high temperature heater (Proceedings of the 68^{th} Meeting of The Japan Society of Applied Physics (Hokkaido Institute of Technology, autumn, 2007) 7P-L-6).

### (c) Method Using Radicalized Se

This is a method using Se radicals generated by a bulb tracking device (Proceedings of the 54^{th} Meeting of The Japan Society of Applied Physics (Aoyama Gakuin University, spring, 2007) 29P-ZW-10)

### (d) Method Using a Photoexcitation Process

This is a method in which KrF excimer laser light (e.g. wavelength of 248 nm, 100 Hz) or YAG laser light (e.g., wavelength of 266 nm, 10 Hz) is applied to a surface of a substrate during the three-stage deposition (Proceedings of the 54^{th} Meeting of The Japan Society of Applied Physics (Aoyama Gakuin University, spring, 2007) 29P-ZW-14).

### 2) Selenidation Method

The selenidation method is also called a two-step deposition method. In this method, a metal precursor of a laminate film such as Cu layer/In layer or (Cu—Ga) layer/In layer is formed by sputtering, deposition, electrodeposition, or the like, then the formed film is heated up to approximately 450° C. to approximately 550° C. in selenium vapor or hydrogen selenide to thereby produce a selenium compound such as Cu(In₁₋ₓGaₓ)Se₂ as a result of a thermal diffusion reaction. This particular method is called a vapor phase selenidation method, but other than this, there is a solid phase selenidation method in which a solid phase of selenium is deposited on a metal precursor film, and the solid phase of the selenium is selenided by a solid diffusion reaction using the solid phase of selenium as a selenium source. The only method which has currently been succeeded in a mass production of a large area is a selenidation method in which a metal precursor film is formed by sputtering, which is suitable for production of large area, and the metal precursor is selenided in hydrogen selenide.

According to this method, however, the film expands about twice in its volume at the time of selenidation, and thus the internal strain is generated, and voids of approximately a few millimeters are formed in the formed film. These internal strain and voids adversely affect to the adhesion to the substrate or properties of the solar battery and become factors to limit the photoelectric conversion efficiency (B. M. Basol, V. K. Kapur, C. R. Leidholm, R. Roe, A. Halani, and G. Norsworthy: NREL/SNL Photovoltaics Prog. Rev. Proc. 14th Conf.—A Joint Meeting (1996) AIP Conf. Proc. 394.).

In order to avoid such rapid cubic expansion of the film at the time of the selenidation, a method in which selenium is previously added to the metal precursor film at a certain ratio (T. Nakada, R. Ohnishi, and A. Kunioka: “CuInSe₂-Based Solar Cells by Se-Vapor Selenization from Se-Containing Precursors” Solar Energy Materials and Solar Cells 35 (1994) pp. 204-214), and use of a multilayer precursor film in which selenium is placed between metal thin films (e.g., laminating Cu layer/In layer/Se layer . . . Cu layer/In layer/Se layer) (T. Nakada, K. Yuda, and A. Kunioka: “Thin Films of CuInSe₂ Produced by Thermal Annealing of Multilayers with Ultra-Thin stacked Elemental Layers” Proc. Of 10th European Photovoltaic Solar Energy Conference (1991) pp. 887-890) have been proposed. By these, the aforementioned problem of the expansion of the deposition can be avoided at a certain degree.

However, there is a problem that is applied to all methods of selenidation, including the methods described above. That is a problem that there is an extremely low degree of freedom for controlling the film composition, as the metal laminate film whose composition is set is used from the beginning and this is then selenided. For example, currently a graded band gap CIGS thin film in which a Ga concentration is gradually changed in the thickness direction is currently used for the high efficiency CIGS solar battery. In order to form such thin film by the selenidation method, there is a method in which a Cu—Ga alloy film is deposited at first, and the Ga concentration is made gradually changed in the thickness direction using natural thermal diffusion at the time of the selenidation (K. Kushiya, I. Sugiyama, M. Tachiyuki, T. Kase, Y. Nagoya, O. Okumura, M. Sato, O. Yamase and H. Takeshita: Tech. Digest 9th Photovoltaic Science and Engineering Conf. Miyazaki, 1996 (Intn.PVSEC-9, Tokyo, 1996) p. 149).

### 3) Sputtering Method

As sputtering is suitable for a deposition of a large area, various methods have been proposed as a formation method of a CuInSe₂ thin film. Examples thereof include a method using CuInSe₂ polycrystal as a target, and a two-source sputtering method in which Cu₂Se and In₂Se₃ are used as a target, and mixed gas of H₂Se and Ar are used as sputtering gas (J. H. Ermer, R. B. Love, A. K. Khanna, S. C. Lewis and F. Cohen: “CdS/CuInSe₂ Junctions Fabricated by DC Magnetron Sputtering of Cu₂Se and In₂Se₃” Proc. 18th IEEE Photovoltaic Specialists Conf. (1985) pp. 1655-1658). Moreover, there has been proposed a three-source sputtering method in which a Cu target, In target, and Se or CuSe target is subjected to sputtering in Ar gas (T. Nakada, K. Migita, A. Kunioka: “Polycrystalline CuInSe₂ Thin Films for Solar Cells by Three-Source Magnetron Sputtering” Jpn. J. Appl. Phys. 32 (1993) L1169-L1172, and T. Nakada, M. Nishioka, and A. Kunioka: “CuInSe₂ Films for Solar Cells by Multi-Source Sputtering of Cu, In, and Se—Cu Binary Alloy” Proc. 4th Photovoltaic Science and Engineering Conf. (1989) 371-375).

### 4) Hybrid Sputtering Method

Suppose that the problem of the aforementioned sputtering method is damages of a surface of the film due to Se negative ions or high energy Se particles, this can be avoided by changing only Se to thermal vapor. Nakata et al. have formed a CIS thin film having a small number of defects by a hybrid sputtering method in which the metals of Cu and In are deposited by DC sputtering and only Se is deposited by vapor deposition, and have produced a CIS solar battery having a conversion efficiency of more than 10% (T. Nakada, K. Migita, S, Niki, and A. Kunioka: “Microstructural Characterization for Sputter-Deposited CuInSe₂ Films and Photovoltaic Devices” Jpn. Appl. Phys. 34 (1995) 4715-4721). Moreover, before Nakata et al., Rockett et al. reported a hybrid sputtering method for replacing toxic H₂Se gas with Se vapor (A. Rockett, T. C. Lommasson, L. C. Yang, H. Talieh, P. Campos and J. A. Thornton: Proc. 20th IEEE Photovoltaic Specialists Conf. (1988)1505). Further back in the date, there was proposed a method in which sputtering was carried out in Se vapor so as to supplement insufficient Se in the film (S. Isomura, H. Kaneko, S. Tomioka, I. Nakatani, and K. Masumoto: Jpn. J. Appl. Phys. 19 (Suppl. 19-3)(1980) 23).

### 5) Mechanochemical Process

Raw materials for each composition of CIGS were placed into a container of a planetary ball mill, the raw materials were mixed by physical energy to thereby obtain CIGS powder. Thereafter, it was applied onto a substrate by screen printing, and subjected to annealing to thereby obtain a film of CIGS (T. Wada, Y. Matsuo, S, Nomura, Y. Nakamura, A. Miyamura, Y. Chia, A. Yamada, M. Konagai, Phys. stat. sol.(a),vol. 203 (2006) p 2593).

### 6) Other Methods

As other formation methods of a CIGS film, for example, screen printing, close space sublimation, MOCVD, spraying are used. In the screen printing, spraying and the like, a thin film consisted of particles formed of the components of Ib group element, IIIb group element, VIb group element and compounds thereof is formed on a substrate, and crystals of desired compositions are obtained by heat treatment or heat treatment in atmosphere of VIb group element. For example, after coating oxide particles to thereby form a thin film, the thin film is heated in hydrogen selenide atmosphere. A thin film of an organic metal compound containing a PVSEC-17 PL5-3, or metal-VIb group element bond is formed on a substrate by spraying or printing, is thermally decomposed to thereby obtain a desired inorganic thin film. In case of S, examples thereof include metal mercaptide, thiosalt of metal, dithiosalt of metal, thiocarbonate of metal, dithiocarbonate of metal, trithiocarbonate of metal, thiocarbamate of metal and dithiocarbamate of metal (JP-A Nos. 09-74065 and 09-74213).

### —Value of Band Gap and Distribution Control—

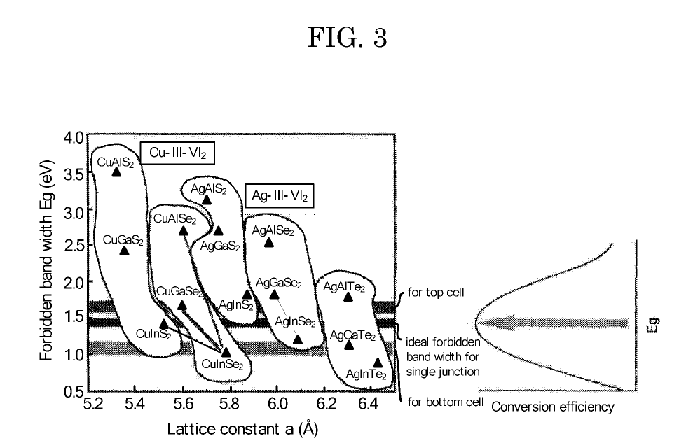

A semiconductor formed of various combinations of I group element-III group element-VI group element is preferably used for the light absorption layer of the solar battery. The one well known in the art is illustrated in FIG. 3, FIG. 3 is a diagram showing a relationship between a lattice constant and band gap of a semiconductor formed of Ib group element, Mb group element and VIb group element. Various forbidden band widths (band gaps) can be obtained by changing the composition ratio. In the case where photons of large energy are injected to the semiconductor by the band gap, the energy larger than the band gap is lost as heat. It has been known by a theoretical calculation that the maximum conversion efficiency with the combination of the spectrum of sun light and the band gap is approximately 1.4 eV to approximately 1.5 eV. For the purpose of increasing the conversion efficiency of the CTGS solar battery, the band gap of high conversion efficiency is obtained, for example, by increasing the concentration of Ga of Cu(InₓGa₁₋ₓ)S₂, the concentration of Al of Cu(InₓAlₓ)S₂, or the concentration of S of CuInGa(S,Se). In case of Cu(InₓGa₁₋ₓ)S₂, the maximum conversion efficiency can be adjusted in the range of 1 eV to 1.68 eV.

Note that, in FIG. 3, Cu(In₁₋ₓGaₓ)Se₂(CIGS) is a mixed crystal of CuInSe₂ and CuGaSe₂. The forbidden band width can be controlled in the range of 1.04 eV to 1.68 eV by changing the Ga concentration x. Other mixed crystals are Cu(InAl)Se₂, Ag(InGa)Se₂, CuIn(S,Se)₂, AlIn(S,Se)₂.

Moreover, the band structure can be graded by changing the composition ratio in the film thickness direction. There are two types of band gaps, which are a single graded band gap in which the band gap is increased in the direction from the light incident side to the opposite electrode side, and a double graded band gap in which the band gap is reduced in the direction from the light incident side to the PN junction part, and the band gap is increased as passed through the PN junction part. Such solar battery is disclosed, for example, in T. Dullweber, A new approach to high-efficiency solar cells by band gap grading in Cu(In,Ga)Se₂ chalcopyrite semiconductors, Solar Energy Materials & Solar Cells, Vol. 67,p. 145-150 (2001). In any of these cases, carriers excited by light is accelerated and thus becomes easier to arrive to the electrode as the electric field is internally generated due to the graded band structure, and a change of combination with recombination center is reduced, to thereby improve generating efficiency (International Publication No. WO 2004/090995).

### —Tandem Type—

By using a plurality of semiconductors each having different band gaps depending on the range of the spectrum, heat loss due to the deviation of photon energy and the band gap is reduced, and thus the generation efficiency can be increased. The one using a plurality of photoelectric conversion layers in lamination in the aforementioned manner is called a tandem type. In case of the two-layer tandem, the generation efficiency can be improved for example by using a combination of 1.1 eV and 1.7 eV.

### —Structure Other Than Photoelectric Conversion Layer—

For a n-type semiconductor which forms a junction with the group compound semiconductor, for example, II-VI group compounds such as CdS, ZnO, ZnS, and Zn (O, S, OH) can be used. Use of these compounds are preferable as these compound can form a contact interface with the photoelectric conversion layer at which recombinations of carriers are not occur (refer to JP-A No. 2002-343987).

### [Substrate]

As the substrate, for example, those listed below can be used. They are a glass plate such as soda-lime glass; a film of polyimide, polyethylene naphthalate, polyether sulfone, polyethylene terephthalate, or aramide; a metal plate of stainless steel, titanium, aluminum, or copper; and a laminate mica substrate described in JP-A No. 2005-317728. Among them, as the substrate for the element for use in the present invention, those in the shape of a film or a foil are preferable.

### [Backside Electrode]

For the backside electrode, for example, metals such as molybdenum, chrome, tungsten and the like can be used. These metal materials are preferable as they tend not to mix with other layers even subjected to a heat treatment. In the case where a photoelectromotive force layer containing a semiconductive layer (light absorption layer) formed of a group compound semiconductor is used, the molybdenum layer is preferably used. Moreover, the recombination center is present at the interface of the light absorption layer CIGS and the backside electrode. For this reason, if the contact area of the backside electrode and the light absorption layer is more than the area necessary for electric conduction, the generating efficiency is lowered. Therefore, in order to reduce the contact area, the electrode layer is, for example, formed to have a structure in which a insulating material and metal are placed in stripes (refer to JP-A No. 09-219530).

Examples of the layer structure of the backside electrode include a super straight structure and a substrate structure. In the case where a photoelectromotive force layer containing a semiconductive layer (light absorption layer) formed of a I-III-VI group compound semiconductor is used, it is more preferably to use the backside electrode of the substrate structure as the conversion efficiency thereof is high.

### [Buffer Layer]

For the buffer layer, for example, CdS, ZnS, ZnS(O,OH), ZnMgO and the like can be used. If the band gap of the light absorption layer is widened, for example, by increasing the concentration of Ga in CIGS, the conduction band thereof becomes a lot bigger than that of ZnO. Therefore, ZnMgO, a conduction band of which has large energy, is preferable for the buffer layer.

### [Transparent Conductive Layer]

After forming the buffer layer, the transparent conductive layer for use in the solar battery of the present invention is formed preferably by coating the metal nanowire aqueous dispersion. Alternatively, a ZnO layer is formed after the buffer layer is formed, and then the metal nanowire aqueous dispersion is applied so as to form the transparent conductive layer.

The formation method of the transparent conductive layer includes applying the metal nanowire aqueous dispersion onto the substrate, and drying. After applying the aqueous dispersion, annealing may be carried out by heating. Here, the heating temperature is preferably 50° C. to 300° C., more preferably 70° C. to 200° C.,

The transparent conductive layer can be used for a transparent electrode of any solar battery. Moreover, the transparent conductive layer can be applied for a crystal (monocrystal, polycrystal, etc.) silicon solar battery, which does not use a transparent electrode, as an electrode for power collection. For the crystal silicon solar battery, a silver deposited electric wires, or electric wires formed of a silver paste is generally used as the powder collection electrode. However, by applying the transparent conductive layer for use in the present invention for the powder collection electrode, the crystal silicon solar battery also obtains high photoelectric conversion efficiency.

Moreover, as the solar battery of the present invention contains a transparent conductive layer having a high transmittance with light of the infrared region and a low sheet resistance, it is suitably used for a solar battery having a large absorption with light of the infrared region, such as an amorphous silicon solar battery of a tandem structure or the like, and a group compound semiconductor solar battery of Cu/In/Se (i.e. CIS type), Cu/In/Ga/Se (i.e. CIGS type), Cu/In/Ga/Se/S (i.e. CIGSS type), or the like.

### EXAMPLES

Hereinafter, examples of the present invention will be explained, but the examples shall not be construed as limiting the scope of the present invention.

In the following examples, a diameter of a metal nanowire, a major axis length of a metal nanowire, a variation coefficient of diameters of metal nanowires, an appropriate wire yield, and a sharpness of angles of a cross section of a metal nanowire are respectively measured in the following manners.

### <Diameter and Major Axis Length of Metal Nanowire>

Three hundred metal nanowires were observed under a transmission electron microscope (TEM)(JEM-2000FX, manufactured by JEOL Ltd.). Based on the average value obtained from the observation, a diameter and major axis length of the metal nanowire were obtained.

### <Variation Coefficient of Diameters of Metal Nanowires>

Three hundred metal nanowires were observed under a transmission electron microscope (TEM)(JEM-2000FX, manufactured by JEOL Ltd.). Based on the average value obtained from the observation, a diameter of the metal nanowire was calculated. Then, a variation coefficient was obtained by calculating the standard deviation and the average value.

### <Appropriate Wire Yield>

Each silver nanowire aqueous dispersion was filtered so as to separate silver nanowires from other particles, and an amount of Ag remained on the filter paper and an amount of Ag passed through the filter paper were respectively measured by means of ICP ATOMIC EMISSION SPECTROMETER (ICPS-8000, manufactured by Shimadzu Corporation). Then the metal content (% by mass) of the metal nanowires (appropriate wires) each having a diameter of 50 nm or less and a length of 5 μm or more was obtained with respect to the total metal particles.

Note that, a membrane filter (FALP 02500, manufactured by Nihon Millipore K.K., having a pore size of 1.0 μm) was used for separating the appropriate wires at the time the appropriate wire yield was obtained.

### <Sharpness of Angle of Cross Section of Metal Nanowire>

The cross sectional shape of the metal nanowire was observed by applying a metal nanowire aqueous dispersion onto a substrate and observing the cross section thereof by means of a transmission electron microscope (TEM)(JEM-2000FX, manufactured by JEOL Ltd.). The circumference of the cross section and total length of each side were respectively measured on the cross sections of the three hundred metal nanowires, and a sharpness was determined as a ratio of “the circumference of the cross section” to the total length of “each side of the cross section”. When the sharpness was less than 75% or less, the angles of the cross sectional shape was considered to be round.

### Preparation Example 1

### Preparation of Loading Solution A

In 50 mL of pure water, 0.51 g of silver nitrate powder was dissolved. Thereafter, IN ammonium hydroxide was added thereto until the mixed solution became transparent. Then, pure water was further added so that the total amount of the solution became 100 mL.

### Preparation Example 2

### Preparation of Loading Solution G

In 140 mL of pure water, 0.5 g of glucose powder was dissolved to thereby prepare a loading solution G.

### Preparation Example 3

### Preparation of Loading Solution H

In 27.5 mL of pure water, 0.5 g of hexadecyl-trimethylammonium bromide (HTAB) powder was dissolved to thereby prepare a loading solution H.

### Production Example 1

### Production of Sample 101, Silver Nanowire Aqueous Dispersion

Into a three-necked flask, 410 mL of pure water, 82.5 mL of the loading solution H, and 206 mL of the loading solution G were added by a funnel while stirring at 20° C. (first step). To this solution, 206 mL of the loading solution A was added at the flow rate of 2.0 mL/min., and stirring revolution of 800 rpm (second step). Ten minutes after the addition of the loading solution A, 82.5 mL of the loading solution H was added thereto. Thereafter, the mixed solution was heated up to 75° C. in terms of the inner temperature thereof at the heating rate of 3° C./min Thereafter, the stirring revolution was dropped to 200 rpm and the mixed solution was heated for 5 hours while stirring.

After cooling the obtained aqueous dispersion, an ultrafiltration module SIP1013 (manufacturer: Asahi Kasei Corporation, molecular cutoff: 6,000), a magnet pump, and a stainless steel cup were connected to each other with silicon tubes so as to form an ultrafiltration device. The silver nanowire dispersion (aqueous solution) was loaded in the stainless steel cup, and then the pump was operated so as to carry out ultrafiltration. At the time when the amount of the filtrate from the module became 50 mL, 950 mL of distilled water was added to the stainless steel cup so as to carry out washing. The washing process was repeated ten times, and then the mother liquid was condensed until the amount thereof became 50 mL.

The obtained sample 101 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 2

### Production of Sample 102, Silver Nanowire Aqueous Dispersion

A silver nanowire aqueous dispersion of sample 102 was prepared in the same manner as in Production Example 1, provided that the initial temperature of the mixed solution of the first step was changed from 20° C. to 25° C.

The obtained sample 102 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 3

### Production of Sample 103, Silver Nanowire Aqueous Dispersion

A silver nanowire aqueous dispersion of sample 103 was prepared in the same manner as in Production Example 1, provided that the initial temperature of the mixed solution of the first step was changed from 20° C. to 30° C.

The obtained sample 103 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 4

### Production of Sample 104, Silver Nanowire Aqueous Dispersion

A silver nanowire aqueous dispersion of sample 104 was prepared in the same manner as in Production Example 1, provided that the amount of the loading solution H added in the first step was changed from 82.5 mL to 70.0 mL.

The obtained sample 104 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 5

### Production of Sample 105, Silver Nanowire Aqueous Dispersion

A silver nanowire aqueous dispersion of sample 105 was prepared in the same manner as in Production Example 1, provided that the amount of the loading solution H added in the first step was changed from 82.5 mL to 65.0 mL.

The obtained sample 105 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 6

### Production of Sample 106, Silver Nanowire Aqueous Dispersion

A silver nanowire aqueous dispersion of sample 106 was prepared in the same manner as in Production Example 1, provided that the flow rate of the loading solution A was changed from 2.0 mL/min to 4.0 mL/min.

The obtained sample 106 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 7

### Production of Sample 107, Silver Nanowire Aqueous Dispersion

A silver nanowire aqueous dispersion of sample 107 was prepared in the same manner as in Production Example 1, provided that the flow rate of the loading solution A was changed from 2.0 mL/min to 6.0 mL/min.

The obtained sample 107 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 8

### Production of Sample 108, Silver Nanowire Aqueous Dispersion

A silver nanowire aqueous dispersion of sample 108 was prepared in the same manner as in Production Example 1, provided that the temperature was elevated from 75° C. at the rate of 1.5° C. per hour in the second step.

The obtained sample 108 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 9

### Production of Sample 109, Silver Nanowire Aqueous Dispersion

A silver nanowire aqueous dispersion of sample 109 was prepared in the same manner as in Production Example 1, provided that the temperature was elevated from 75° C. at the rate of 2.5° C. per hour in the second step.

The obtained sample 109 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 10

### Production of Sample 110, Silver Nanowire Aqueous Dispersion

A silver nanowire aqueous dispersion of sample 110 was prepared in the same manner as in Production Example 1, provided that the temperature in the second step was maintained at 80° C.

The obtained sample 110 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 11

### Production of Sample 111, Silver Nanowire Aqueous Dispersion

A silver nanowire aqueous dispersion of sample 111 was prepared in the same manner as in Production Example 1, provided that the temperature in the second step was maintained at 90° C.

The obtained sample 111 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 12

### Production of Sample 112, Silver Nanowire Aqueous Dispersion

A silver nanowire aqueous dispersion of sample 112 was prepared in the same manner as in Production Example 1, provided that the temperature was elevated from 75° C. at the rate of 3.5° C. per hour in the second step.

The obtained sample 112 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 13

### Production of Sample 113, Silver Nanowire Aqueous Dispersion

A silver nanowire aqueous dispersion of sample 113 was prepared in the same manner as in Production Example 1, provided that the temperature in the second step was maintained at 95° C.

The obtained sample 113 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 14

### Production of Sample 114, Silver Nanowire Aqueous Dispersion

A silver nanowire aqueous dispersion of sample 114 was prepared in the same manner as in Production Example 1, provided that the initial temperature of the mixed solution of the first step was changed from 20° C. to 40° C.

The obtained sample 114 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 15

### Production of Sample 115, Silver Nanowire Aqueous Dispersion

A silver nanowire aqueous dispersion of sample 115 was prepared in the same manner as in Production Example 1, provided that the amount of the loading solution H added in the first step was changed from 82.5 mL to 50.0 mL.

The obtained sample 115 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

### Production Example 16

### Production of Sample 116, Silver Nanowire Aqueous Dispersion

A silver nanowire aqueous dispersion of sample 116 was prepared in the same manner as in Production Example 1, provided that the flow rate of the loading solution. A was changed from 2.0 mL/min to 8.0 mL/min.

The obtained sample 116 was measured in terms of the diameter of the silver nanowire, the major axis of the silver nanowire, the appropriate wire yield, the variation coefficient of diameters of the silver nanowires, and the sharpness of the angles of the cross section of the silver nanowire. The results are shown in Table 1.

TABLE 1

| | | | Major axis | | Variation | Sharpness |
|---|---|---|---|---|---|---|
| | | Diameter | length of | Appropriate | coefficient of | of cross- |
| | | of wire | wire | wire yield | diameters of | section |
| | Sample No. | (nm) | (μm) | (mass %) | wires (%) | angles (%) |
| Production | 101 | 17.6 | 36.7 | 82.6 | 18.3 | 47.3 |
| Example 1 | | | | | | |
| Production | 102 | 23.8 | 41.8 | 78.3 | 29.3 | 37.3 |
| Example 2 | | | | | | |
| Production | 103 | 48.3 | 32.3 | 62.7 | 33.4 | 43.4 |
| Example 3 | | | | | | |
| Production | 104 | 16.2 | 13.7 | 76.3 | 22.3 | 48.1 |
| Example 4 | | | | | | |
| Production | 105 | 17.8 | 6.8 | 63.2 | 27.4 | 58.3 |
| Example 5 | | | | | | |
| Production | 106 | 19.4 | 41.8 | 71.7 | 24.3 | 45.3 |
| Example 6 | | | | | | |
| Production | 107 | 16.3 | 32.4 | 58.4 | 28.4 | 49.2 |
| Example 7 | | | | | | |
| Production | 108 | 19.2 | 37.5 | 78.3 | 33.7 | 42.3 |
| Example 8 | | | | | | |
| Production | 109 | 18.3 | 34.2 | 67.3 | 38.2 | 47.2 |
| Example 9 | | | | | | |
| Production | 110 | 16.3 | 28.3 | 77.2 | 22.7 | 57.4 |
| Example 10 | | | | | | |
| Production | 111 | 18.2 | 26.3 | 62.7 | 31.2 | 68.3 |
| Example 11 | | | | | | |
| Production | 112 | 16.3 | 12.7 | 58.2 | 45.4 | 46.1 |
| Example 12 | | | | | | |
| Production | 113 | 18.2 | 13.7 | 77.6 | 38.1 | 89.4 |
| Example 13 | | | | | | |
| Production | 114 | 62.4 | 34.6 | 68.4 | 43.4 | 32.7 |
| Example 14 | | | | | | |
| Production | 115 | 18.2 | 3.7 | 54.2 | 27.4 | 37.2 |
| Example 15 | | | | | | |
| Production | 116 | 19.2 | 13.2 | 28.3 | 38.1 | 43.2 |
| Example 16 | | | | | | |

### Example 1

### Production of Microcrystal Silicon Solar Battery (Substrate Type)

### —Production of Photoelectric Conversion Element 201—

Onto a polyimide substrate, a silver electrode having a film thickness of 200 nm, and an aluminum-doped zinc oxide thin layer having a film thickness of approximately 30 nm were formed by DC magnetron sputtering. Onto the aluminum-doped zinc oxide thin layer, a n-type microcrystal silicon layer having a film thickness of 50 nm, an i-type microcrystal silicon layer having a film thickness of 2,000 nm, and a p-type microcrystal silicon layer having a film thickness of 50 nm were formed by plasma-enhanced chemical vapor deposition (PECVD), and a tin-doped indium oxide (ITO) thin film (transparent conductive layer) having a film thickness of 300 nm was further formed thereon as a transparent electrode to thereby produce an photoelectric conversion element 201.

### —Production of Photoelectric Conversion Element 202—

A photoelectric conversion element 202 was produced in the same manner as in the photoelectric conversion element 201, provided that as a transparent electrode, a tin-doped indium oxide (ITO) thin film (transparent conductive layer) having a film thickness of 0.8 μm was further formed.

### —Production of Photoelectric Conversion Element 203—

A photoelectric conversion element 203 was produced in the same manner as in the photoelectric conversion element 201, provided that as a transparent electrode, the silver nanowire aqueous dispersion of the sample 101 was used instead of ITO. Namely, after the p-type microcrystal silicon was formed, it was placed in the N² gas atmosphere, and then the sample 101, which was the aqueous dispersion, was applied onto the p-type microcrystal silicon so that the coated amount thereof became 0.1 g/m² in terms of Ag conversion. After the sample 101 was applied, it was heated at 150° C. for 10 minutes to thereby produce the photoelectric conversion element 203.

### —Productions of Photoelectric Conversion Elements 204 to 207—

Photoelectric conversion elements 204 to 207 were produced in the same manner as in the photoelectric conversion element 203, using the samples of the silver nanowire aqueous dispersion shown in Table 2.

### Example 2

### Production of Amorphous Solar Battery (Super Straight Type)

### —Production of Photoelectric Conversion Element 301—

On a glass substrate, fluorine-doped thin oxide (transparent conductive layer) having a film thickness of 700 nm was formed by MOCVD. On the fluorine-doped thin oxide, a p-type amorphous silicon having a film thickness of 15 nm, an i-type amorphous silicon having a film thickness of 350 nm, and a n-type amorphous silicon having a film thickness of 30 nm were formed by plasma-enhanced chemical vapor deposition (PECVD), and then a gallium-doped zinc oxide layer having a thickness of 20 nm and a silver layer having a thickness of 200 nm were further formed thereon as a backside reflecting electrode to thereby produce a photoelectric conversion element 301.

### —Production of Photoelectric Conversion Element 302—

A photoelectric conversion element 302 was produced in the same manner as in the photoelectric conversion element 301, provided that fluorine-doped thin oxide (transparent conductive layer) having a film thickness of 1.0 μm as a transparent electrode.

### —Production of Photoelectric Conversion Element 303—

A photoelectric conversion element 303 was produced in the same manner as in the photoelectric conversion element 301, provided that, instead of forming fluorine-doped thin oxide, the silver nanowire aqueous dispersion of the sample 101 was applied onto the glass substrate so that the coated amount thereof became OA g/m² in terms of Ag conversion, and then heated at 150° C. for 10 minutes to form a transparent electrode.

### —Productions of Photoelectric Conversion Elements 304 to 307—

Photoelectric conversion elements 304 to 307 were produced in the same manner as in the photoelectric conversion element 303, using the samples of the silver nanowire aqueous dispersion shown in Table 2.

### Example 4

### Production of CIGS Solar Battery (Substrate Type)

### —Production of Photoelectric Conversion Element 401—

On a soda-lime glass substrate, a molybdenum electrode having a film thickness of 500 nm was formed by DC magnetron sputtering, a Cu(In_{0.6}Ga_{0.4})Se₂ thin film, which was a chalcopyrite semiconductor material, having a film thickness of approximately 2.5 μm was formed thereon by vapor deposition, a cadmium sulfide thin film having a film thickness of 50 nm was formed thereon by solution deposition, a zinc oxide thin film having a film thickness of 50 nm was formed thereon by MOCVD, and a boron-doped zinc oxide tin film (transparent conductive layer) having a film thickness of 100 nm was formed thereon by DC magnetron sputtering, to thereby produce a photoelectric conversion element 401.

### —Production of Photoelectric Conversion Element 402—

A photoelectric conversion element 402 was produced in the same manner as in the photoelectric conversion element 401, provided that as a transparent electrode, a boron-doped zinc oxide thin film (transparent conductive layer) having a film thickness of 1.0 μm was formed.

### —Production of Photoelectric Conversion Element 403—

A photoelectric conversion element 403 was produced in the same manner as in the photoelectric conversion element 401, provided that the silver nanowire aqueous dispersion of the sample 101 was used instead of the boron-doped zinc oxide as a transparent electrode. Specifically, after forming the cadmium sulfide thin film, the sample 101, which was the silver nanowire aqueous dispersion, was applied on the cadmium sulfide thin film so that the coated amount thereof became 0.1 g/m² on Ag conversion. After the sample 101 was applied, it was heated at 150° C. for 10 minutes to thereby produce the photoelectric conversion element 403.

### —Productions of Photoelectric Conversion Elements 404 to 407—

Photoelectric conversion elements 404 to 407 were produced in the same manner as in the photoelectric conversion element 403, using the samples of the silver nanowire aqueous dispersion shown in Table 2.

### Example 5

On a glass substrate, a transparent conductive layer was formed in the same manner as to each of the transparent conductive layers of the photoelectric elements 201 to 207, 301 to 307, and 401 to 407 of Examples 2 to 4, to thereby prepare samples 201A to 207A, 301A to 307A, and 401A to 407A. In order to make the numbers of the samples of the transparent conductive layer to those of the photoelectric conversion elements, A was added after the numbers of the samples of the photoelectric conversion elements.

Then, the obtained samples 201A to 207A, 301A to 307A, and 401A to 407A in Example 5 were evaluated in terms of the average transmittance at the wavelength of 1,100 nm to 2,000 nm and a sheet resistance in the following manners. The results are shown in Table 2.

### <Transmittance of Transparent Conductive Layer>

A transmittance of each sample was measured at the wavelength of 400 nm to 2,700 nm by means of UV-3150 manufactured by Shimadzu Corporation, and then the average transmittance thereof at the wavelength of 1,100 nm to 2,000 nm was obtained.

### <Sheet Resistance>

Each sample was subjected to the measurement of the sheet resistance by means of Loresta-GP MCP-T600 manufactured by Mitsubishi Chemical Corporation.

TABLE 2

| | | Average | | |
|---|---|---|---|---|
| | Transparent | transmittance | Sheet | |
| | conductive | at 1,100 nm to | resistance | |
| Sample | layer | 2,000 nm (%) | (ohm/sq.) | Notes |
| 201A | ITO | 60 | 11 | Comparative |
| | | | | Example |
| 202A | ITO | 81 | 280 | Comparative |
| | | | | Example |
| 203A | Sample 101 | 90 | 8 | Present Invention |
| 204A | Sample 201 | 87 | 10 | Present Invention |
| 205A | Sample 102 | 90 | 8 | Present Invention |
| 206A | Sample 103 | 88 | 8 | Present Invention |
| 207A | Sample 107 | 87 | 9 | Present Invention |
| 301A | Fluorin-doped | 65 | 14 | Comparative |
| | tin oxide | | | Example |
| 302A | Fluorin-doped | 83 | 330 | Comparative |
| | tin oxide | | | Example |
| 303A | Sample 101 | 90 | 8 | Present Invention |
| 304A | Sample 201 | 87 | 10 | Present Invention |
| 305A | Sample 102 | 90 | 8 | Present Invention |
| 306A | Sample 103 | 88 | 8 | Present Invention |
| 307A | Sample 107 | 87 | 9 | Present Invention |
| 401A | Boron-doped | 70 | 12 | Comparative |
| | zinc oxide | | | Example |
| 402A | Boron-doped | 82 | 305 | Comparative |
| | zinc oxide | | | Example |
| 403A | Sample 101 | 90 | 8 | Present Invention |
| 404A | Sample 201 | 87 | 10 | Present Invention |
| 405A | Sample 102 | 90 | 8 | Present Invention |
| 406A | Sample 103 | 88 | 8 | Present Invention |
| 407A | Sample 107 | 87 | 9 | Present Invention |

From the results shown in Table 2, it was found that a transparent conductive layer having a high transmittance at 1,100 nm to 2,000 nm and low sheet resistance could be attained by using the silver nanowire aqueous dispersion for the transparent conductive layer.

### Example 6

On a silver plate having a thickness of 100 μm, a transparent conductive layer was formed in the same manner as to each of the transparent conductive layers of the photoelectric elements 201 to 203, 301 to 303, and 403 to 403 of Examples 2 to 4, to thereby prepare samples 201B to 203B, 301B to 303B, and 401B to 403B. In order to make the numbers of the samples of the transparent conductive layer to those of the photoelectric conversion elements, B was added after the numbers of the samples of the photoelectric conversion elements.

Then, the obtained samples 201B to 203BA, 301B to 303BA, and 401B to 403B in Example 6 were subjected to the measurements of the resistance in the film thickness direction and a ratio (Rs/Rt) of the resistance within the plane in the following manners. The results are shown in Table 3.

<Resistance in Film Thickness Direction and Ratio (Rs/Rt) of Resistance within Plane>

The thus obtained samples 201B to 203B, 301B to 303B, and 401B to 403B were each placed on a metal electrode, resistance Rt in the film thickness direction was measured by applying voltage to the silver plate and the transparent conductive layer. Moreover, two metal electrodes were placed on two regions of the transparent conductive layer, respectively, and resistance Rs in the planar direction was measured by applying voltage to the two metal electrodes. Then, Rs/Rt was obtained. The results are shown in Table 3.

TABLE 3

| | Transparent | | |
|---|---|---|---|
| | conductive | | |
| Sample | layer | Rs/Rt | Notes |
| 201B | ITO | 1.1 | Comparative |
| | | | Example |
| 202B | Sample 101 | 3.0 | Present invention |
| 203B | Sample 201 | 2.5 | Present invention |
| 301B | Fluorine-dope | 1.1 | Comparative |
| | tin oxide | | Example |
| 302B | Sample 101 | 3.0 | Present invention |
| 303B | Sample 201 | 2.5 | Present invention |
| 401B | Boron-doped | 1.2 | Comparative |
| | zinc oxide | | Example |
| 402B | Sample 101 | 3.0 | Present invention |
| 403B | Sample 201 | 2.5 | Present invention |

Next, the prepared solar battery samples 201 to 207, 301 to 307, and 401 to 407 were evaluated in terms of the solar battery properties (conversion efficiency) in the following manner. The results are shown in Table 4.

### <Evaluation of Solar Battery Element>

Each of the prepared solar batteries was exposed to the simulated sunlight (AM 1.5, 100 mW/cm²) to thereby measure the solar battery properties (conversion efficiency).

TABLE 4

| | Transparent | | |
|---|---|---|---|
| | conductive | Conversion | |
| Sample | layer | efficiency (%) | Notes |
| 201 | ITO | 6 | Comparative |
| | | | Example |
| 202 | ITO | 6 | Comparative |
| | | | Example |
| 203 | Sample 101 | 8 | Present Invention |
| 204 | Sample 201 | 7 | Present Invention |
| 205 | Sample 102 | 8 | Present Invention |
| 206 | Sample 103 | 8 | Present Invention |
| 207 | Sample 107 | 7 | Present Invention |
| 301 | Fluorin-doped | 7 | Comparative |
| | tin oxide | | Example |
| 302 | Fluorin-doped | 7 | Comparative |
| | tin oxide | | Example |
| 303 | Sample 101 | 9 | Present Invention |
| 304 | Sample 201 | 8 | Present Invention |
| 305 | Sample 102 | 9 | Present Invention |
| 306 | Sample 103 | 9 | Present Invention |
| 307 | Sample 107 | 8 | Present Invention |
| 401 | Boron-doped | 9 | Comparative |
| | zinc oxide | | Example |
| 402 | Boron-doped | 9 | Comparative |
| | zinc oxide | | Example |
| 403 | Sample 101 | 11 | Present Invention |
| 404 | Sample 201 | 10 | Present Invention |
| 405 | Sample 102 | 11 | Present Invention |
| 406 | Sample 103 | 11 | Present Invention |
| 407 | Sample 107 | 10 | Present Invention |

From the results shown in Table 4, it was found that high conversion efficiency could be attained in any type of the solar batteries by using the transparent conductive layer containing the metal nanowires. Note that, the difference in the effect between the comparative examples and the present inventions is 1% to 2% in number, but this difference is considered to be important as known in the art.

The solar battery of the present invention contains a transparent conductive layer having a high transmittance with light of the infrared region and a low sheet resistance, and has high conversion efficiency. Therefore, it is suitably for, for example, an amorphous silicon solar battery of a tandem structure or the like, and a I-III-VI group compound semiconductor solar battery of Cu/In/Se (i.e. CIS type), Cu/In/Ga/Se (i.e. CIGS type), Cu/In/Ga/Se/S (i.e. CIGSS type), or the like.

What is claimed is:

1. A solar battery, comprising:
a transparent conductive layer having an average transmittance of 80% or more with an electromagnetic wave having a wavelength of 1,100 nm to 2,000 nm, and a sheet resistance of 20 ohm/sq. or less, the transparent conductive layer containing metal nanowires.

2. The solar battery according to claim 1, wherein the transparent conductive layer has a larger conductivity in a planar direction thereof than that in a thickness direction thereof.

3. The solar battery according to claim 1, wherein the metal nanowire has a diameter of 50 mn or less, and a length of 5 μm or more, and wherein an amount of the metal nanowires contained in total metal particles of the transparent conductive layer is 50% by mass or more on the basis of a metal content.

4. The solar battery according to claim 1, wherein the metal nanowire contains silver.

5. The solar battery according to claim 1, further comprising a light-absorbing semiconductor layer containing silicon.

6. The solar battery according to claim 1, further comprising a light-absorbing semiconductor layer formed of Ib group element, IIIb group element, and VIb group element.

7. The solar battery according to claim 6, wherein the light-absorbing semiconductor layer contains at least one element selected from Cu, Ag, In, Ga, S, Se and Te.
